(19) United States
(12) Patent Application Publication
(10) Pub. No.: US 2025/0198000 A1
(43) Pub. Date: Jun. 19, 2025

(54) SUBSTRATE PROCESSING APPARATUS

(71) Applicant: TES CO., LTD, Yongin-si (KR)

(72) Inventors: Kyung-Ho JANG, Yongin-si (KR); Min-Wook KANG, Yongin-si (KR); Byeong-Ho YUN, Yongin-si (KR); Jun-Ho HONG, Yongin-si (KR)

(73) Assignee: TES CO., LTD, Yongin-si (KR)

(21) Appl. No.: 18/983,165

(22) Filed: Dec. 16, 2024

(30) Foreign Application Priority Data
Dec. 18, 2023 (KR) 10-2023-0184753

(51) Int. Cl. C23C 16/455; B05B 1/18; B05B 13/02; C23C 16/458

(52) U.S. Cl. CPC C23C 16/45565; B05B 1/18; B05B 13/0278; B05B 13/0285; C23C 16/4583

(57) ABSTRACT

A substrate processing apparatus includes a chamber, an upper showerhead, a substrate supporter, a lower showerhead assembly, first and second elevation units, and first and second tilting units. The chamber provides a processing space for a substrate, and the upper showerhead is provided in an upper region of an interior of the chamber. The substrate supporter is provided in the interior of the chamber to support the substrate, and the lower showerhead assembly is provided in an interior of the substrate supporter to supply process gas to the substrate. The first elevation unit adjusts a gap between the substrate and the lower showerhead assembly, and the first tilting unit tilts the lower showerhead assembly with respect to the substrate. The second elevation unit adjusts a gap between the substrate and the upper showerhead, and the second tilting unit tilts the substrate with respect to the upper showerhead.

### CROSS-REFERENCE TO RELATED APPLICATIONS

A claim for priority under 35 U.S.C. § 119 is made to Korean Patent Application No. 10-2023-0184753 filed on Dec. 18, 2023, in the Korean Intellectual Property Office, the entire contents of which are hereby incorporated by reference.

### BACKGROUND OF THE INVENTION

### Field of the Invention

The present invention relates to an apparatus for processing a substrate, and more particularly to a substrate processing apparatus capable of adjusting a distance between a substrate and an upper showerhead or adjusting a distance between the substrate and a lower showerhead, and further capable of tilting the substrate with respect to the upper showerhead or tilting the lower showerhead with respect to the substrate.

### Description of the Related Art

In the prior art, a substrate processing apparatus deposits a thin film or a thin layer of a predetermined thickness on one side of a substrate, for example on a top surface of the substrate. In this case, when the thin films are deposited and superimposed on the top surface of the substrate, a stress of the thin films can cause the substrate to bow.

When the substrate is bowed in this manner, it becomes difficult to position the substrate in a correct position when the substrate is processed in various substrate processes that follow, and this bowing phenomenon reduces precision of the processes, especially while the precision of the substrate processes is increasing day by day. Therefore, to prevent the bowing phenomenon of the substrate described above, a thin film of a predetermined thickness is deposited on a bottom surface of the substrate.

Such a substrate processing apparatus is provided with an upper heater that supplies purge gas and the like to a top portion of the substrate, and a lower showerhead that supplies process gas to a bottom portion of the substrate.

Meanwhile, for a device that supplies the process gas toward the bottom surface of the substrate, such as the substrate processing apparatus described above, a distance between the substrate and the upper showerhead and a distance between the substrate and the lower showerhead are important. This is because when plasma is used during the process on the substrate, it is necessary to control a gap between the substrate and the upper showerhead so that the plasma does not generate between the substrate and the upper showerhead. In addition, a gap between the substrate and the lower showerhead is also important when the process gas is supplied toward the bottom surface of the substrate.

Moreover, due to various factors, the substrate and the upper showerhead may not be parallel and thus need to be aligned to be parallel. Further, the substrate and the lower showerhead may not be parallel and thus need to be aligned to be parallel. In contrast, it may be necessary to intentionally dispose the substrate and the upper showerhead in a non-parallel configuration and dispose the substrate and the lower showerhead in a non-parallel configuration, during the process on the substrate. In this case, it may be necessary to tilt the substrate with respect to the upper showerhead, or to tilt the lower showerhead with respect to the substrate.

### SUMMARY OF THE INVENTION

The present invention is contemplated to solve problems in the prior art mentioned above. Thus, it is an object of the present invention to provide a substrate processing apparatus capable of adjusting a distance between a substrate and an upper showerhead or adjusting a distance between the substrate and a lower showerhead, and further capable of tilting the substrate with respect to the upper showerhead or tilting the lower showerhead with respect to the substrate.

To solve the above problems, the present invention may provide a substrate processing apparatus comprising: a chamber configured to provide a processing space for a substrate; an upper showerhead provided in an upper region of an interior of the chamber; a substrate supporter provided in the interior of the chamber and configured to support the substrate; a lower showerhead assembly provided in an interior of the substrate supporter and configured to supply process gas toward a bottom surface of the substrate; a first elevation unit configured to adjust a gap between the substrate and the lower showerhead assembly by raising or lowering the lower showerhead assembly; a first tilting unit configured to tilt the lower showerhead assembly with respect to the substrate; a second elevation unit configured to adjust a gap between the substrate and the upper showerhead by raising or lowering the substrate supporter and the lower showerhead assembly; and a second tilting unit configured to tilt the substrate with respect to the upper showerhead by tilting the substrate supporter and the lower showerhead assembly.

The first elevation unit may include: a first elevation plate connected to a shaft of the lower showerhead assembly; and a first elevation actuator configured to raise and lower the first elevation plate.

Further, the substrate processing apparatus may further comprise a first vertical connection bar connected to the first elevation actuator, wherein the first elevation plate may be configured to be raised and lowered along the first vertical connection bar.

Meanwhile, the first tilting unit may include: a first tilting plate connected to a shaft of the lower showerhead assembly; and a first tilting actuator configured to tilt the first tilting plate.

Further, one side of the first tilting plate may be connected to a first vertical connection bar, and a first elevation plate, which is connected to the shaft of the lower showerhead assembly, may be connected to the first vertical connection bar.

Moreover, the substrate processing apparatus may further comprise a second elevation plate connected to a lower end part of the substrate supporter, wherein the first tilting actuator may be connected to the second elevation plate by a first tilting housing.

In this case, the shaft of the lower showerhead assembly may be disposed by passing through the second elevation plate.

Meanwhile, the second elevation unit may include: a second elevation plate connected to a lower end part of the substrate supporter and a shaft of the lower showerhead assembly; and a second elevation actuator configured to raise and lower the second elevation plate.

In this case, the substrate processing apparatus may further comprise: a first elevation plate connected to the shaft of the lower showerhead assembly; a first vertical connection bar connected to the first elevation plate; a first tilting plate connected to the first vertical connection bar; and a first tilting housing connecting the first tilting plate and the second elevation plate.

Further, the substrate processing apparatus may further comprise a second vertical connection bar connected to the second elevation actuator, wherein the second elevation plate may be configured to be raised and lowered along the second vertical connection bar.

Meanwhile, the second tilting unit may include: a second tilting plate connected to a lower end part of the substrate supporter and a shaft of the lower showerhead assembly; and a second tilting actuator configured to tilt the second tilting plate.

Further, the second tilting plate may be connected to a second vertical connection bar, and a second elevation plate, which is connected to the lower end part of the substrate supporter, may be connected to the second vertical connection bar to be raised and lowered along the second vertical connection bar. In this case, the substrate processing apparatus may further comprise: a first elevation plate connected to the shaft of the lower showerhead assembly; a first vertical connection bar connected to the first elevation plate; a first tilting plate connected to the first vertical connection bar; and a first tilting housing connecting the first tilting plate and the second elevation plate.

In this case, the first vertical connection bar and the second vertical connection bar may be symmetrically disposed with respect to the shaft of the lower showerhead assembly.

Further, the substrate processing apparatus may further comprise a second tilting housing connected to a lower part of the chamber, wherein the second tilting actuator and the second tilting plate may be connected to each other by the second tilting housing.

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a side sectional view of a substrate processing apparatus according to one embodiment of the present invention;

FIG. 2 is a side sectional view illustrating a lower showerhead assembly raised by a first elevation unit;

FIG. 3 is a side sectional view illustrating the lower showerhead assembly tilted in one direction with respect to the substrate by a first tilting unit;

FIG. 4 is a side sectional view illustrating both a substrate supporter and the lower showerhead assembly raised by a second elevation unit;

FIG. 5 is a side sectional view illustrating the substrate supporter and lower showerhead assembly tilted by a second tilting unit,

FIG. 6 is a perspective view of a second tilting actuator of the substrate processing apparatus;

FIG. 7 is a sectional view taken along VII-VII line of FIG. 6; and

FIGS. 8A and 8B are plan views of a first tilting plate and a second tilting plate, respectively.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as “comprise”, “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, a configuration of a substrate processing apparatus according to an embodiment of the present invention will be described in detail with reference to accompanying drawings.

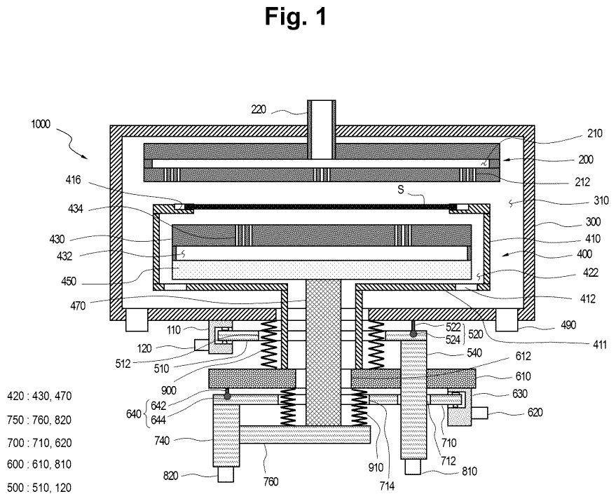

FIG. 1 is a side sectional view of a substrate processing apparatus 1000 according to one embodiment of the present invention.

Referring to FIG. 1, the substrate processing apparatus 1000 may include a chamber 300 providing a processing space 310 in which a process for a substrate S is performed, an upper showerhead 200 provided in an upper region of an inside or interior of the chamber 300 to supply purge gas, a substrate supporter 400 provided in a lower region of the inside or interior of the chamber 300 to support the substrate S, and a lower showerhead assembly 420 provided in an inside or interior of the substrate supporter 400 to supply process gas toward a bottom surface of the substrate S.

Specifically, the chamber 300 may provide the processing space 310 in which various components necessary for the process on the substrate S are housed.

Any one side of the chamber 300 may be provided with an opening (not shown) through which the substrate S is loaded into the processing space 310 or unloaded from the processing space 310, and a door (not shown) may be provided to the opening.

The upper region of the chamber 300 may be provided with the upper showerhead 200 for supplying the purge gas, such as inert gas, towards a top surface of the substrate S. In addition, the upper region of the interior of the chamber 300 may be provided with an upper heater (not shown) for heating the substrate S. The upper heater may be provided separately from such an upper showerhead 200, or may be integrated with the upper showerhead 200.

Meanwhile, an upper part of the chamber 300 may be connected with an upper supply channel 220 through which the purge gas is supplied.

The purge gas supplied along the upper supply channel 220 may be fed downward through the upper showerhead 200.

The purge gas supplied at the upper showerhead 200 may be supplied toward the processing space 310 below and may prevent the process gas supplied from the lower showerhead 430 from entering into the upper showerhead 200.

Specifically, the upper showerhead 200 may provide a first buffer space 210. Therefore, the purge gas supplied via the upper supply channel 220 may diffuse in the first buffer space 214 and may be supplied downward via first supply holes 212 of the upper showerhead 200. In FIG. 1, the first supply holes 212 are shown as being formed in only a portion of the upper showerhead 200 for illustrative convenience, but the first supply holes 212 may be formed across the entirety of the upper showerhead 200.

Meanwhile, the substrate processing apparatus 1000 may further include a Radio Frequency (RF) power supply (not shown) that applies RF power to at least one of the upper showerhead 200 and the lower showerhead 430.

For example, the upper showerhead 200 may be connected to the RF power supply (not shown) to be provided with the RF power. That is, the upper showerhead 200 may serve as an upper electrode. In this case, the lower showerhead 430 may be grounded to serve as a lower electrode.

When the RF power is applied to the upper showerhead 200 during the process on the substrate S, the upper showerhead 200 may be in capacitive coupling with the lower showerhead 430, and plasma may be generated between the upper showerhead 200 and the lower showerhead 430 to facilitate the process on the bottom surface of the substrate S.

Meanwhile, the substrate supporter 400 may be provided to move up and down in a lower region of the processing space 310, and may support an edge of the bottom surface of the substrate S. The lower showerhead assembly 420 may be provided inside the substrate supporter 400, and the process gas may be supplied by the lower showerhead assembly 420.

The substrate supporter 400 may include a substrate holder 410 supporting the edge of the bottom surface of the substrate S, and an extension 411 connected to a lower end part of the substrate holder 410 and extending downwardly. An interior or inside of the substrate holder 410 may be provided with the lower showerhead assembly 420 for supplying the process gas toward the bottom surface of the substrate S.

The substrate holder 410 may extend upwardly from the extension 411, and may have a top end thereof bent inwardly.

In this case, a recess 416 may be formed at a top or upper end part of the substrate holder 410. Thus, when the substrate S is seated at the substrate holder 410, the substrate S may be inserted into the recess 416 to support a bottom surface of the edge of the substrate S.

Additionally, the substrate holder 410 may be configured in a form of a cylinder of which a sidewall surrounds an entire side circumference of the lower showerhead 430, or although not shown in the accompanying drawings, may be configured in a form of a plurality of columns disposed to be spaced apart around the side circumference of the lower showerhead 430.

Meanwhile, the lower showerhead assembly 420 may include the lower showerhead 430 for supplying the process gas towards the bottom surface of the substrate S, and a shaft 470 extending downwardly. Further, the lower showerhead assembly 420 may further include a lower plate 450 at which a heat exchange channel (not shown) is formed. Moreover, the lower plate 450 may be provided with a heater for heating the substrate S.

In this case, when the lower end part of the extension 411 and a lower end part of the shaft 470 protrude through a lower part of the chamber 300, a first bellows 900 may be provided to enclose the lower end part of the extension 411 and the lower end part of the shaft 470.

An upper end part of the first bellows 900 may be connected to a bottom or lower surface of the chamber 300, and a lower end part of the first bellows 900 may be connected to a second elevation plate 610, which will be described later.

Meanwhile, the process gas may be supplied to the lower showerhead 430 via a lower supply line (not shown) which passes through the shaft 470. The lower showerhead 430 may be grounded to generate the plasma between the upper showerhead 200 and the lower showerhead 430 as described above.

The lower showerhead 430 may be provided with a second buffer space 432, and the second buffer space 432 may be located between the lower showerhead 430 and the lower plate 450. Alternatively, although not shown in the drawings, the second buffer space 432 may be provided inside the lower showerhead 430.

Meanwhile, the heat exchange channel (not shown) may be formed at the lower plate 450, such that a heat exchange fluid or the like flows along the heat exchange channel to regulate a temperature inside the chamber 300 or a temperature of the process gas through heat exchange.

Further, the lower plate 450 may serve to support the lower showerhead 430. In this case, the lower showerhead 430 may be connected to an upper (or top) surface of the lower plate 450.

Meanwhile, a space between sides of the lower showerhead 430 and the lower plate 450 and an inner surface of the substrate holder 410 may form an exhaust channel 422.

In this case, a portion of the process gas supplied from the lower showerhead 430 may be discharged to the lower region of the interior of the chamber 300 through the exhaust channel 422 and an opening 412 of the extension 411, and then may be exhausted to an outside of the chamber 300 through an exhaust port 490 provided at the lower part of the chamber 300.

Meanwhile, the purge gas supplied downwardly from the upper showerhead 200 may flow into the lower region of the chamber 300 and may be exhausted to the outside of the chamber 300 through the exhaust port 490.

Meanwhile, in a device that supplies the process gas toward the bottom surface of the substrate S, such as the substrate processing apparatus 1000 according to the present invention, a distance between the substrate S and the upper showerhead 200 and a distance between the substrate S and the lower showerhead 430 are important. This is because when the plasma is used during the process on the substrate S, it is necessary to control a gap between the substrate S and the upper showerhead 200 such that the plasma does not generate between the substrate S and the upper showerhead 200. In addition, a gap between the substrate S and the lower showerhead 430 also becomes important when the process gas is supplied toward the bottom surface of the substrate S.

Moreover, due to various factors, the substrate S and the upper showerhead 200 may not be arranged to be parallel and thus need to be aligned to be parallel. Further, the substrate S and the lower showerhead 430 may not be arranged to be parallel and thus need to be aligned to be parallel. In contrast, it may be required to intentionally dispose the substrate S and the upper showerhead 200 not to be parallel, and dispose the substrate S and the lower showerhead 430 not to be parallel, during the process on the substrate S. In this case, it may be required to tilt the substrate S with respect to the upper showerhead 200 or tilt the lower showerhead 430 with respect to the substrate S.

For the tilting and/or the distance adjustment as described above, the substrate processing apparatus 1000 of the present invention may include a first elevation unit 750 for raising (or lifting) and lowering the lower showerhead assembly 420 to adjust the gap between the substrate S and the lower showerhead assembly 420, a first tilting unit 700 for tilting the lower showerhead assembly 420 with respect to the substrate S, a second elevation unit 600 for raising (or lifting) and lowering the substrate supporter 400 and the lower showerhead assembly 420 to adjust the gap between the substrate S and the upper showerhead 200, and a second tilting unit 500 for tilting the substrate supporter 400 and the lower showerhead assembly 420 to tilt the substrate S with respect to the upper showerhead 200.

The components provided at the lower part of the chamber 300 will be discussed first, and then the first elevation unit 750, the first tilting unit 700, the second elevation unit 600, and second tilting unit 500 will be discussed.

In the following, left side (or end) portions of certain members or components in the drawings are referred to as a term “one side” and opposite right side (or end) portions thereof are referred to as a term “the other side” for better understanding of the configurations of the present invention. The term “one side” may be replaced by a term “a first side (or end)” and the term “the other side” may be replaced by a term “a second side (or end)”, and vice versa. Further, it should be appreciated that the positions of the members or components are not limited to the following descriptions, and such members or components could be arranged at any positions available under the concept and principle of operation of the present invention.

A second tilting housing 110 may be connected to the lower or bottom part of the chamber 300, and a second tilting plate 510 may be connected to the second tilting housing 110 to be tiltable. In this case, a second tilting actuator 120 may be connected to the second tilting housing 110.

Specifically, one side of the second tilting plate 510 may be connected to the second tilting housing 110, and the other side of the second tilting plate 510 may be connected to a second tilting connector 520. The second tilting connector 520 may include a second support bar 522 connected to the lower part of the chamber 300 and a second rotator 524 connected to an end of the second support bar 522. The second rotator 524 may be formed in a spherical, semi-circular or curved shape such that the second rotator 524 may be rotatably or pivotably connected to the second tilting plate 510. Therefore, when one side of the second tilting plate 510 is moved up and down by the second tilting actuator 120, the entire second tilting plate 510 may be tilted by rotating or pivoting about the second tilting connector 520.

Further, an opening 512 may be formed at the second tilting plate 510, and the lower end parts of the shaft 470 and the extension 411 may pass through the opening 512.

Meanwhile, the second vertical connection bar 540 may be disposed along a vertical direction and may be connected to a lower part of the other side of the second tilting plate 510. A second elevation plate 610 to which the lower end part of the substrate supporter 400 or the lower end part of the extension 411 of the substrate supporter 400 is connected, may be connected to the second vertical connection bar 540, to be raised and lowered.

That is, the second elevation plate 610 may move up and down along the second vertical connection bar 540. To this end, a linear motion (LM) actuator or guide (not shown) may be disposed inside the second vertical connection bar 540, and a second elevation actuator 810 may be connected to the second vertical connection bar 540. Accordingly, the LM actuator may be driven by the second elevation actuator 810 to cause the second elevation plate 610 to be raised and lowered along the second vertical connection bar 540.

Further, an opening 612 may be formed at the second elevation plate 610, such that the shaft 470 of the lower showerhead assembly 420 may be disposed passing through the opening 612.

Meanwhile, a second bellows 910 may be provided between the second elevation plate 610 and a first elevation plate 760 which will be described later. That is, the second bellows 910 may be disposed between the second elevation plate 610 and the first elevation plate 760 while enclosing the lower end part of the shaft 470.

Further, a first tilting housing 630 may be connected to a lower part of the other side of the second elevation plate 610, and a first tilting plate 710 may be connected to the first tilting housing 630 to be tiltable. In this case, a first tilting actuator 620 may be connected to the first tilting housing 630.

Specifically, the other side of the first tilting plate 710 may be connected to the first tilting housing 630, and one side of the first tilting plate 710 may be connected to a first tilting connector 640. The first tilting connector 640 may include a first support bar 642 connected to the lower part of the second elevation plate 610 and a first rotator 644 connected to an end of the first support bar 642. The first rotator 644 may be formed in a spherical, semi-circular or curved shape and connected to one side of the first tilting plate 710. Thus, when the first tilting actuator 620 is actuated, the other side of the first tilting plate 710 may be raised and lowered, so that the whole first tilting plate 710 may be tilted by rotating or pivoting about the first tilting connector 640.

In addition, a first vertical connection bar 740 may be disposed along a vertical direction and may be connected at a lower part of one side of the first tilting plate 710. A first elevation plate 760 to which the shaft 470 of the lower showerhead assembly 420 is connected, may be connected to the first vertical connection bar 740 to be raised and lowered.

That is, the first elevation plate 760 may be moved up and down along the first vertical connection bar 740. To this end, a linear motion (LM) actuator or guide (not shown) may be disposed inside the first vertical connection bar 740, and a first elevation actuator 820 may be connected to the first vertical connection bar 740. Accordingly, the LM actuator may be driven by the first elevation actuator 820 to cause the first elevation plate 760 to be raised and lowered along the first vertical connection bar 740.

Further, an opening 714 may be formed at the first tilting plate 710, such that the shaft 470 of the lower showerhead assembly 420 may be disposed passing through the opening 714.

Further, an additional opening 712 may be formed at the first tilting plate 710, such that the second vertical connection bar 540 may be disposed passing through the additional opening 712.

Meanwhile, the first vertical connection bar 740 and the second vertical connection bar 540 may be symmetrically disposed about the shaft 470. Thereby, the spatial restriction necessitated for installing the first vertical connection bar 740 and the second vertical connection bar 540 may be overcome, and furthermore, when the first elevation actuator 820 and the second elevation actuator 810 are actuated, the force caused by such actuation may be distributed to reduce the load acting on the first vertical connection bar 740 and the second vertical connection bar 540, respectively.

Under the configuration as described above, operations of the first elevation unit 750, the first tilting unit 700, the second elevation unit 600, and the second tilting unit 500 will now be described.

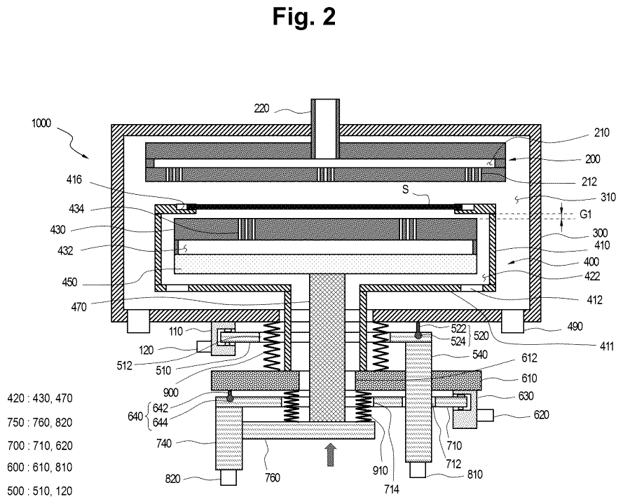

FIG. 2 is a side sectional view illustrating a state in which only the lower showerhead assembly 420 is raised by the first elevation unit 750.

Referring to FIG. 2, the first elevation unit 750 may include the first elevation plate 760 connected to the shaft 470 of the lower showerhead assembly 420, and the first elevation actuator 820 for raising or lowering the first elevation plate 760.

In this case, the first elevation actuator 820 may be connected to the first vertical connection bar 740 as described above, and the first elevation plate 760 may be raised and lowered along the first vertical connection bar 740.

Accordingly, when the first elevation actuator 820 is driven, the LM actuator provided inside the first vertical connection bar 740 may be driven, such that the first elevation plate 760 may be raised and lowered along the first vertical connection bar 740.

This causes the lower showerhead assembly 420 to be raised and lowered as shown in FIG. 2, thereby adjusting a distance or gap G1 between the bottom surface of the substrate S and the lower showerhead 430.

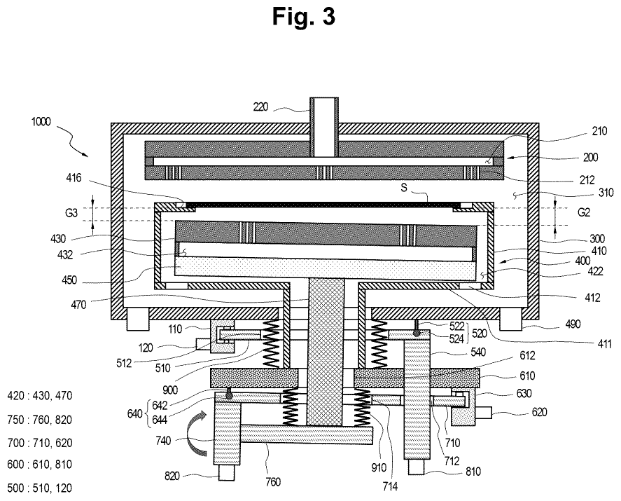

Meanwhile, FIG. 3 is a side sectional view illustrating a state in which the lower showerhead assembly 420 is tilted in one direction with respect to the substrate S by the first tilting unit 700.

Referring to FIG. 3, the first tilting unit 700 may include the first tilting plate 710 connected to the shaft 470 of the lower showerhead assembly 420, and the first tilting actuator 620 for tilting the first tilting plate 710.

Further, the first tilting actuator 620 may be connected to the second elevation plate 610 by the first tilting housing 630 as described above.

Moreover, the shaft 470 of the lower showerhead assembly 420 may be disposed through the opening 612 of the second elevation plate 610.

In this case, the first tilting plate 710 may be connected to the first elevation plate 760, which is connected to the lower end part of shaft 470 of the lower showerhead assembly 420, by the first vertical connection bar 740, as described above.

Thus, when the first tilting actuator 620 is driven while the first elevation plate 760 is fixed to the first vertical connection bar 740, the first tilting plate 710 may be rotated or pivoted about the first tilting connector 640 so as to be tilted, and the first elevation plate 760 may also be rotated about the first tilting connector 640 to be tilted together.

Accordingly, as shown in FIG. 3, the lower showerhead assembly 420 may rotate in one direction, for example, in a clockwise direction, such that the lower showerhead 430 is tilted with respect to the bottom surface of the substrate S, and thus the gaps G2, G3 between the top or upper surface of the lower showerhead 430 and the bottom surface of the substrate S may vary in different regions between the lower showerhead 430 and the substrate S.

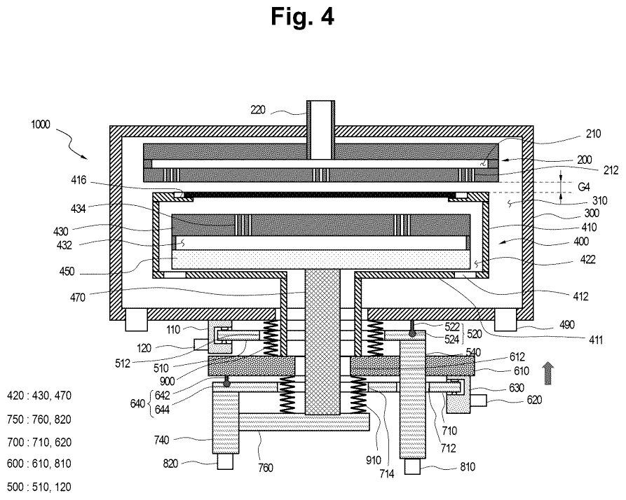

FIG. 4 is a side sectional view illustrating a state in which both the substrate supporter 400 and the lower showerhead assembly 420 are raised by the second elevation unit 600.

Referring to FIG. 4, the second elevation unit 600 may include the second elevation plate 610 connected to the lower end part of the substrate supporter 400 and the shaft 470 of the lower showerhead assembly 420, and the second elevation actuator 810 for raising or lowering the second elevation plate 610.

In this case, the shaft 470 of the lower showerhead assembly 420 may be connected to the first elevation plate 760, and the first elevation plate 760 may be connected to the first vertical connection bar 740, as described above. Further, the first vertical connection bar 740 may be connected to one side of the first tilting plate 710, and the first tilting plate 710 and the second elevation plate 610 may be connected to each other by the first tilting housing 630.

Therefore, the lower end part of the extension 411 of the substrate supporter 400 may be directly connected to the second elevation plate 610, and also the shaft 470 of the lower showerhead assembly 420 may be indirectly connected to the second elevation plate 610, such that the substrate supporter 400 and the lower showerhead assembly 420 are raised and lowered together.

Moreover, the second elevation actuator 810 may be connected to the second vertical connection bar 540, and thus the second elevation plate 610 may be raised and lowered along the second vertical connection bar 540.

Accordingly, when the LM actuator provided inside the second vertical connection bar 540 is driven by the driving of the second elevation actuator 810, the second elevation plate 610 may be raised and lowered along the second vertical connection bar 540.

Due to such a configuration, the substrate supporter 400 and the lower showerhead assembly 420 may be raised and lowered together to adjust the distance or gap G4 between the top surface of the substrate S and the upper showerhead 200, as shown in FIG. 4.

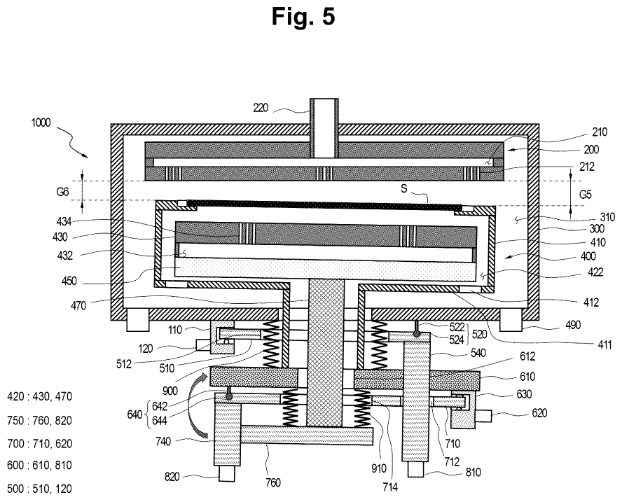

FIG. 5 is a side sectional view illustrating a state in which both the substrate supporter 400 and the lower showerhead assembly 420 are tilted by the second tilting unit 500.

Referring to FIG. 5, the second tilting unit 500 may include the second tilting plate 510 connected to the lower end part of the substrate supporter 400 and the shaft 470 of the lower showerhead assembly 420, and the second tilting actuator 120 for tilting the second tilting plate 510.

In this case, the other side of the second tilting plate 510 may be connected to the second vertical connection bar 540, and the second elevation plate 610, which is connected to the lower end part of the substrate supporter 400, may be connected to the second vertical connection bar 540, as described above. Further, the shaft 470 of the lower showerhead assembly 420 may be connected to the first elevation plate 760, and the first elevation plate 760 may be connected to the first vertical connection bar 740 to be raised and lowered. Moreover, one side of the first tilting plate 710 may be connected to the first vertical connection bar 740, and the other side of the first tilting plate 710 may be connected to the other side of the second elevation plate 610 by the first tilting housing 630.

Thus, when the second tilting actuator 120 is driven, the second tilting plate 510 may be tilted by rotating or pivoting about the second tilting connector 520, and the substrate supporter 400 and the lower showerhead assembly 420 may be tilted together.

Accordingly, as shown in FIG. 5, the substrate supporter 400 and the lower showerhead assembly 420 may all rotate in one direction, for example in a clockwise direction, such that the substrate S is tilted with respect to the bottom or lower surface of the upper showerhead 200, and thus gaps G5, G6 between the bottom or lower surface of the upper showerhead 200 and the top surface of the substrate S may vary in different regions between the upper showerhead 200 and the substrate S.

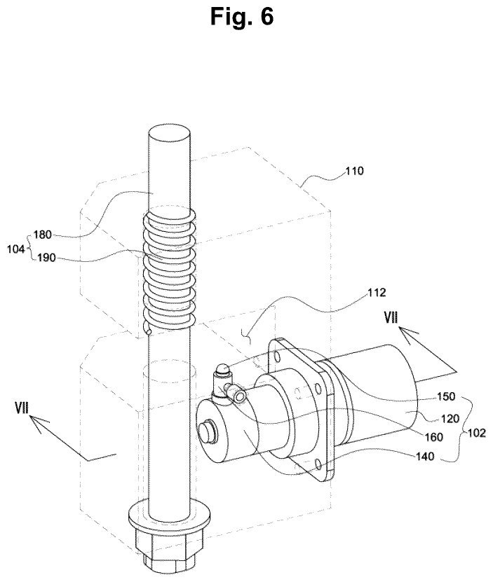

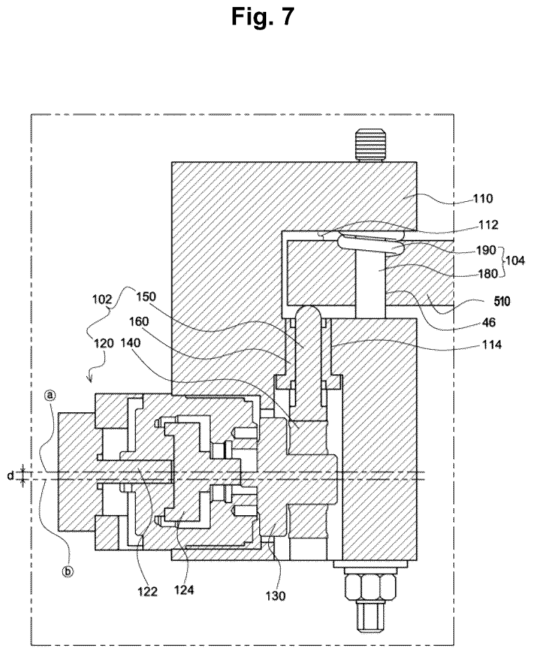

Meanwhile, FIGS. 6 and 7 correspond to drawings illustrating the operation of the previously described tilting actuators. Referring to FIGS. 6 and 7, the second tilting actuator 120 is illustrated and described, and since the first tilting actuator 620 has the same configuration as the second tilting actuator 120, any further description for the first tilting actuator 620 will be omitted.

FIG. 6 is a perspective view of the second tilting actuator 120 of the substrate processing apparatus 1000.

Referring to FIG. 6, the substrate processing apparatus 1000 may be provided with a first adjustment unit 102 for rotating the second tilting plate 510 up and down by a predetermined distance, and a second adjustment unit 104 for preventing the second tilting plate 510 from moving upward by a negative pressure inside the chamber 300.

In other words, the first adjustment unit 102 may rotate one side of the second tilting plate 510 up and down in order to adjust a rotation angle of the second tilting plate 510.

The first adjustment unit 102 may be provided on a second tilting housing 110 which is connected to the lower part of the chamber 300 as shown in FIG. 6. The second tilting housing 110 may be fixed to the lower part of the chamber 300, and may be formed with a recess 112 into which one side of the second tilting plate 510 is inserted. While being inserted into the recess 112, one side of the second tilting plate 510 may be slightly rotated up and down by the first adjustment unit 102, or the lifting of the second tilting plate 510 may be prevented and the height of the second tilting plate 510 may be secured or maintained by the second adjustment unit 104.

Meanwhile, the second adjustment unit 104 may include a spring member 190.

For example, the second tilting housing 110 may be provided with a fixing bar 180 that crosses the recess 112 in the vertical direction, and the spring member 190 may be provided on an upper part of the fixing bar 180. In this case, a through hole 46 through which the fixing bar 180 passes, may be formed in the second tilting plate 510, and the spring member 190 may press the second tilting plate 510 downwardly. The spring member 190 may be configured to prevent the second tilting plate 510 from moving upwardly when the negative pressure is generated inside the chamber 300 as described above. The above configuration is only an example, and it is of course possible to omit the configuration of the fixing bar 180, and to couple the spring member 190 directly to the second tilting housing 110 to press the second tilting plate 510, instead.

FIG. 7 is a cross-sectional view taken along a line VII-VII of FIG. 6.

Referring to FIG. 7, the first adjustment unit 102 may include a cam member 130 that applies a predetermined force to the second tilting plate 510, and the second tilting actuator 120 having a rotation shaft 122, which rotates the cam member 130 and is connected to the cam member 130 by being spaced from a center of rotation of the cam member 130 by a predetermined distance.

The second tilting actuator 120 such as a motor may be provided to the second tilting housing 110, and the rotation shaft 122 extending from the second tilting actuator 120 may be connected to the cam member 130. In this case, the center of rotation of the cam member 130 and the rotation shaft 122 of the second tilting actuator 120 may be connected by being spaced apart by a predetermined distance d. In FIG. 7, \textcircled{a} line corresponds to an imaginary or hypothetical line extending from a center of the rotation shaft 122 of the second tilting actuator 120, and \textcircled{b} line corresponds to an imaginary or hypothetical line extending from the center of rotation of the cam member 130.

That is, the rotation shaft 122 of the second tilting actuator 120 is not connected to the center of rotation of the cam member 130, but rather, the rotation shaft 122 of the second tilting actuator 120 may be connected to a position spaced apart by a predetermined distance from the center of rotation of the cam member 130. In such a configuration, when the rotation shaft 122 of the second tilting actuator 120 is rotated by driving of the second tilting actuator 120, the cam member 130 may be also rotated together.

In this case, since the center of rotation of the cam member 130 is located to be spaced apart from the center of the rotation shaft 122, an outer circumference of the cam member 130 may have a varying distance from the rotation shaft 122 when the cam member 130 rotates. That is, when the cam member 130 rotates, the outer circumference of the cam member 130 may not form a constant circular trajectory, but may form an irregular trajectory in which the distance to the rotation shaft 122 varies. Therefore, when the distance between the outer circumference of the cam member 130 and the rotation shaft 122 becomes relatively long, the second tilting plate 510 may be rotated by being raised upwardly, and conversely, when the distance between the outer circumference of the cam member 130 and the rotation shaft 122 becomes relatively short, the second tilting plate 510 may be rotated by being lowered downwardly.

In this case, the substrate processing apparatus 1000 may further include a bearing element 140 provided between the cam member 130 and the second tilting plate 510 to enclose the outer circumference of the cam member 130 and exert the predetermined force on the second tilting plate 510. The bearing element 140 may prevent the cam member 130 from directly contacting a push bar 150 which will be described later, thereby preventing the wear of the cam member 130 or the push bar 150.

Further, the substrate processing apparatus 1000 may further include a push bar 150 whose one end contacts an outer circumference of the bearing element 140 to exert a predetermined force on the second tilting plate 510 by the rotation of the bearing element 140.

The push bar 150 may be disposed to be movable up and down through a linear bush 160 which passes through an opening 114 provided at the other side of the second tilting housing 110. When the push bar 150 is moved up and down by the rotation of the cam member 130, the linear bush 160 may guide the up and down movement of the push bar 150. Thus, when the bearing element 140 is rotated together by the rotation of the cam member 130, the push bar 150 may be moved up and down to cause the second tilting plate 510 to rotate by raising or lowering the second tilting plate 510.

Further, the push bar 150 may support the second tilting plate 510 to prevent deflection or bending of the second tilting plate 510. That is, since the cam member 130 is engaged with and fixed on the rotation shaft 122 when the cam member 130 is not rotated, a height of an upper end part of the push bar 150 may be fixed or maintained to support the second tilting plate 510 and prevent the deflection thereof.

Meanwhile, a reducer 124 may be positioned between the cam member 130 and the rotation shaft 122. The reducer 124 may decrease the rotational force of the rotation shaft 122 and transmit such rotational force to the cam member 130. In this case, a reduction ratio of the reducer 124 may be determined in correspondence to a maximum distance over which the second tilting plate 510 can be raised and lowered.

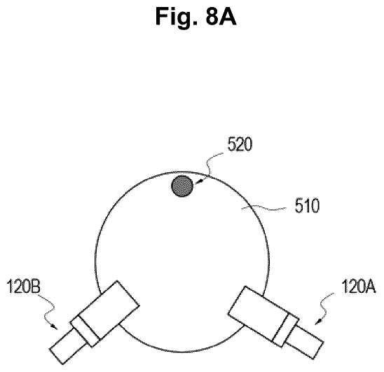

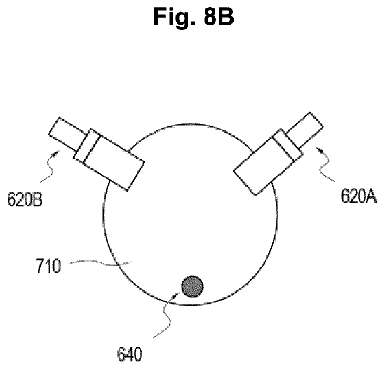

Meanwhile, FIGS. 8A and 8B are plan views of the first tilting plate 710 and second tilting plate 510, which illustrate the first tilting plate 710, the second tilting plate 510, the first tilting actuators 620A, 620B, and the second tilting actuators 120A, 120B. FIG. 8A illustrates the second tilting plate 510 and the second tilting actuators 120A, 120B, and FIG. 8B illustrates the first tilting plate 710 and the first tilting actuators 620A, 620B.

As described above, in order to adjust the tilting angle and tilting direction of the first tilting plate 710 and the second tilting plate 510, it is preferable to provide a plurality of first tilting actuators 620A, 620B and a plurality of second tilting actuators 120A, 120B rather than the single first tilting actuator 620 and the single second tilting actuator 120.

For example, as shown in FIG. 8A, two second tilting actuators 120A, 120B may be provided to the second tilting plate 510. The number of the second tilting actuators 120A, 120B is described as an example, and it is also possible to provide more than two actuators.

In this case, the second tilting plate 510 may be supported by the plurality of second tilting actuators 120A, 120B, or may be supported by the second tilting connector 520 and the plurality of second tilting actuators 120A, 120B. In the following, the second tilting plate 510 is assumed to have one second tilting connector 520 and two second tilting actuators 120A, 120B.

Here, the second tilting connector 520 may serve to support the second tilting plate 510 to be tilted, as described above.

When the second tilting plate 510 is provided with one second tilting connector 520 and two second tilting actuators 120A, 120B as shown in FIG. 8A, the second tilting connector 520 and the second tilting actuators 120A, 120B may be symmetrically arranged. For example, the second tilting connector 520 and the second tilting actuators 120A, 120B may be disposed at a center angle of 120 degrees, respectively, with respect to the central portion of the second tilting plate 510.

In case of having such a plurality of second tilting actuators 120A, 120B, the tilting angles generated by the second tilting actuator 120A, 120B may be the same, or may be different from each other.

By making the tilting angles caused by the second tilting actuators 120A, 120B the same or different from each other, the resultant tilting angle and the tilting direction of the second tilting plate 510 may be adjusted.

Meanwhile, the configuration of the first tilting plate 710, the first tilting actuators 620A, 620B, and the first tilting connector 640 as shown FIG. 8B is similar to the configuration shown in FIG. 8A, and thus further descriptions are omitted.

The substrate processing apparatus according to the present invention has the technical advantages as follows.

According to the present invention with the configuration as described above, the distance between the substrate and the upper showerhead or the distance between the substrate and the lower showerhead can be adjusted, and furthermore, the substrate can be tilted with respect to the upper showerhead or the lower showerhead can be tilted with respect to the substrate.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing apparatus comprising:
a chamber;
an upper showerhead provided in an upper region of an interior of the chamber;
a substrate supporter provided in the interior of the chamber and configured to support a substrate;
a lower showerhead assembly provided in an interior of the substrate supporter and configured to supply process gas toward a bottom surface of the substrate;
a first elevation unit configured to adjust a gap between the substrate and the lower showerhead assembly by raising or lowering the lower showerhead assembly;
a first tilting unit configured to tilt the lower showerhead assembly with respect to the substrate;
a second elevation unit configured to adjust a gap between the substrate and the upper showerhead by raising or lowering the substrate supporter and the lower showerhead assembly; and
a second tilting unit configured to tilt the substrate with respect to the upper showerhead by tilting the substrate supporter and the lower showerhead assembly.

2. The substrate processing apparatus of claim 1, wherein the first elevation unit includes:
a first elevation plate connected to a shaft of the lower showerhead assembly; and
a first elevation actuator configured to raise and lower the first elevation plate.

3. The substrate processing apparatus of claim 2, further comprising a first vertical connection bar connected to the first elevation actuator, wherein the first elevation plate is configured to be raised and lowered along the first vertical connection bar.

4. The substrate processing apparatus of claim 1, wherein the first tilting unit includes:
a first tilting plate connected to a shaft of the lower showerhead assembly; and
a first tilting actuator configured to tilt the first tilting plate.

5. The substrate processing apparatus of claim 4, wherein one side of the first tilting plate is connected to a first vertical connection bar, and
wherein a first elevation plate, which is connected to the shaft of the lower showerhead assembly, is connected to the first vertical connection bar.

6. The substrate processing apparatus of claim 4, further comprising a second elevation plate connected to a lower end part of the substrate supporter,
wherein the first tilting actuator is connected to the second elevation plate by a first tilting housing.

7. The substrate processing apparatus of claim 6, wherein the shaft of the lower showerhead assembly is disposed by passing through the second elevation plate.

8. The substrate processing apparatus of claim 1, wherein the second elevation unit includes:
a second elevation plate connected to a lower end part of the substrate supporter and a shaft of the lower showerhead assembly; and
a second elevation actuator configured to raise and lower the second elevation plate.

9. The substrate processing apparatus of claim 8, further comprising:
a first elevation plate connected to the shaft of the lower showerhead assembly;
a first vertical connection bar connected to the first elevation plate;
a first tilting plate connected to the first vertical connection bar; and
a first tilting housing connecting the first tilting plate and the second elevation plate.

10. The substrate processing apparatus of claim 8, further comprising a second vertical connection bar connected to the second elevation actuator,
wherein the second elevation plate is configured to be raised and lowered along the second vertical connection bar.

11. The substrate processing apparatus of claim 1, wherein the second tilting unit includes:
a second tilting plate connected to a lower end part of the substrate supporter and a shaft of the lower showerhead assembly; and
a second tilting actuator configured to tilt the second tilting plate.

12. The substrate processing apparatus of claim 11, wherein the second tilting plate is connected to a second vertical connection bar,
wherein a second elevation plate, which is connected to the lower end part of the substrate supporter, is connected to the second vertical connection bar to be raised and lowered along the second vertical connection bar, and
further comprising:
a first elevation plate connected to the shaft of the lower showerhead assembly;
a first vertical connection bar connected to the first elevation plate;
a first tilting plate connected to the first vertical connection bar; and
a first tilting housing connecting the first tilting plate and the second elevation plate.

13. The substrate processing apparatus of claim 12, wherein the first vertical connection bar and the second vertical connection bar are symmetrically disposed with respect to the shaft of the lower showerhead assembly.

14. The substrate processing apparatus of claim 11, further comprising a second tilting housing connected to a lower part of the chamber,
wherein the second tilting actuator and the second tilting plate are connected to each other by the second tilting housing.
